(19) United States
(12) Patent Application Publication
(10) Pub. No.: US 2016/0266972 A1
(43) Pub. Date: Sep. 15, 2016

(54) MEMORY CONTROLLER, STORAGE DEVICE AND DECODING METHOD

(71) Applicant: Kabushiki Kaisha Toshiba, Minato-ku (JP)

(72) Inventors: Ryo YAMAKI, Yokohama (JP); Haruka Obata, Ota (JP)

(73) Assignee: Kabushiki Kaisha Toshiba, Minato-ku (JP)

(21) Appl. No.: 14/845,890

(22) Filed: Sep. 4, 2015

Related U.S. Application Data
(60) Provisional application No. 62/130,978, filed on Mar. 10, 2015.

(51) Int. Cl. G06F 11/10; H03M 13/45; G11C 29/52

(52) U.S. Cl. CPC G06F 11/1068; G11C 29/52; H03M 13/45

(57) ABSTRACT

An embodiment includes: a first decoder configured to calculate first distance information indicating a squared Euclidean distance between a first decoded word obtained by decoding a first received word read from a nonvolatile memory and the first received word, calculate a decoding success rate based on the first distance information, and calculate a first extrinsic value vector based on the first decoding success rate; and a second decoder configured to decode a result obtained by adding a second received word read from the nonvolatile memory to the rearranged set of the first extrinsic values corresponding to the second codeword, calculate second distance information based on a second decoded word obtained by the decoding, calculate a decoding success rate based on the second distance information, and calculate a second extrinsic value based on the second decoding success rate.

### CROSS-REFERENCE TO RELATED APPLICATIONS

This application is based upon and claims the benefit of priority from U.S. Provisional Application No. 62/130,978, filed on Mar. 10, 2015; the entire contents of which are incorporated herein by reference.

### FIELD

Embodiments described herein relate generally to a memory controller, a storage device, and a decoding method.

### BACKGROUND

In a general storage device, data is stored while being applied with error correcting coding. A product code whose component codewords are arranged in a two dimensional array is known as an example of error correcting coding.

### BRIEF DESCRIPTION OF THE DRAWINGS

FIG. 1 is a block diagram of an exemplary configuration of a storage device according to the embodiment;

FIG. 2 is a diagram of an exemplary configuration of a product code according to the embodiment;

FIG. 3 is a diagram of an exemplary configuration of a decoder according to the embodiment;

FIG. 4 is a diagram of an exemplary reading process according to the embodiment;

FIG. 5 is an explanatory diagram of soft bit read;

FIG. 6 is a diagram of an exemplary LLR table;

FIG. 7 is a diagram of an exemplary configuration of an SISO Decoder;

FIG. 8 is a flowchart of an exemplary iterative SISO decoding process according to the embodiment;

FIG. 9 is a conceptual diagram of an exemplary relationship between the distance information and the decoding success rate φ according to the embodiment; and

FIG. 10 is a flowchart of an exemplary process for calculating an extrinsic value according to the embodiment.

### DETAILED DESCRIPTION

A memory controller according to the present embodiment includes a first decoder configured to: perform a first decoding using, a first set of soft input values, a first received word corresponding to a first codeword read as the first set of soft input values from a nonvolatile memory; calculate first distance information indicating a squared Euclidean distance between a first decoded word obtained by the first decoding and the first set of soft input values based on the first decoded word; calculate a first decoding success rate indicating a probability that the first decoded word is a correct decoding result based on the first distance information; calculate a first set of extrinsic values based on the first decoding success rate; and output the first set of extrinsic values. The memory controller further includes a second decoder configured to: perform a second decoding using, as a second set of soft input values, a result obtained by adding a second received word corresponding to a second codeword read as a set of soft decision values from the nonvolatile memory to a rearranged set of the first extrinsic values corresponding to the second codeword; calculate second distance information indicating a squared Euclidean distance between a second decoded word obtained by the second decoding and the second set of soft input values based on the second decoded word, calculate a second decoding success rate indicating a probability that the second decoded word is a correct decoding result based on the second distance information, calculate a second set of extrinsic values based on the second decoding success rate, and output the second set of extrinsic values.

The memory controller, storage device, decoding method according to the embodiment will be described in detail with reference to the appended drawings. Note that the present invention is not limited to the embodiment.

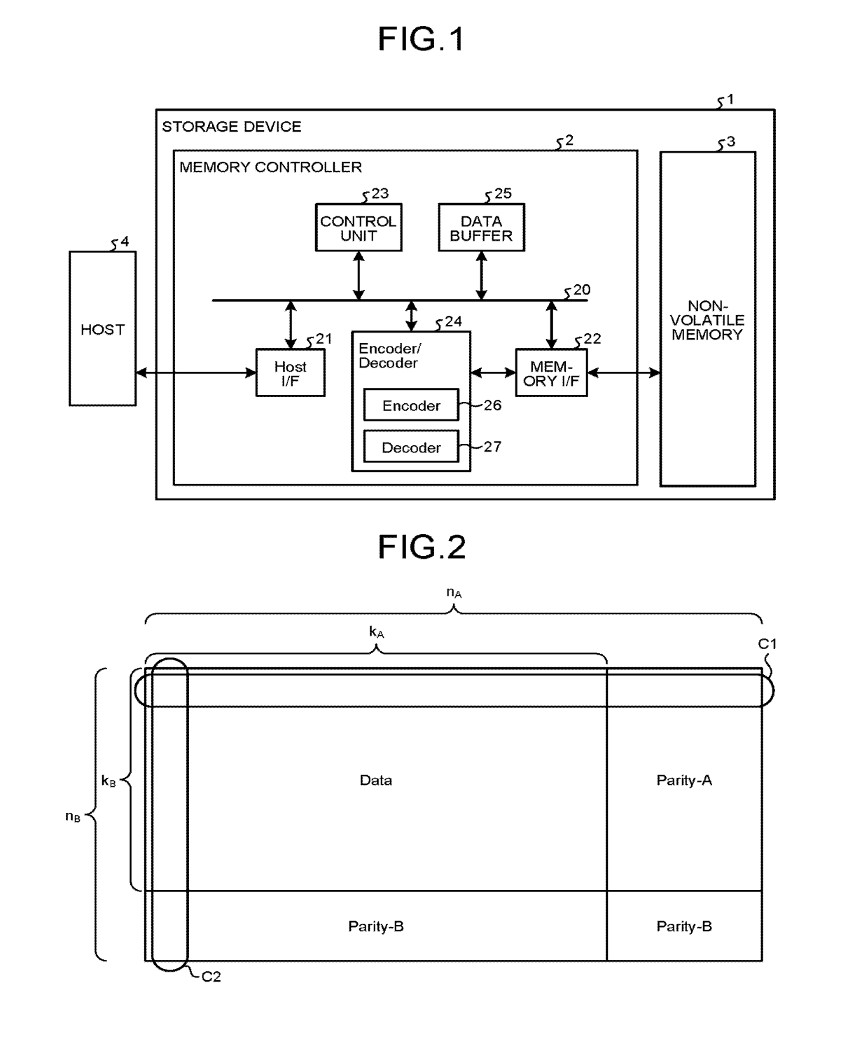

FIG. 1 is a block diagram of an exemplary configuration of a storage device according to the embodiment. A storage device 1 according to the present embodiment includes a memory controller 2, and a nonvolatile memory 3. The storage device 1 may be connected to a host 4. FIG. 1 illustrates the storage device 1 connected to the host 4. The host 4 is an electronic device, for example, a personal computer, or a mobile terminal.

The non-volatile memory 3 such as a NAND memory stores data in a non-volatile manner. Herein, an example in which a NAND memory is used as the nonvolatile memory 3 will be described. Note that, however, a storage unit such as a three-dimensionally-structured flash memory, a Resistance Random Access Memory (ReRAM), or a Ferroelectric Random Access Memory (FeRAM) may be used as the nonvolatile memory 3 instead of the NAND memory. Furthermore, an example in which a semiconductor memory is used as the storage unit will be described herein. However, the error correcting process according to the present embodiment may be applied to a storage device using a storage unit other than the semiconductor memory.

The storage device 1 may be, for example, a memory card including the memory controller 2 and the nonvolatile memory 3 in a package, or a Solid State Drive (SSD).

The memory controller 2 controls the writing to the nonvolatile memory 3 in accordance with a write command (request) from the host 4. Similarly, the memory controller 2 controls the reading from the nonvolatile memory 3 in accordance with a read command from the host 4. The memory controller 2 includes a host interface (Host I/F) 21, a memory interface (memory I/F) 22, a control unit 23, an encoder and decoder (Encoder/Decoder) 24, and a data buffer 25. The Host I/F 21, the memory I/F 22, the control unit 23, the Encoder/Decoder 24, and the data buffer 25 are connected to each other via an internal bus 20.

The Host I/F 21 performs a process in accordance with the interface specification between the Host I/F 21 and the host 4 to output, for example, instructions or user data received from the host 4 to the internal bus 20. The Host I/F 21 transmits, for example, the user data read from the nonvolatile memory 3, or the response from the control unit 23 to the host 4. Note that the data to be written to the nonvolatile memory 3 in accordance with the write request from the host 4 is referred to as the user data in the present embodiment.

The memory I/F 22 writes data to the nonvolatile memory 3 in a writing process in accordance with the instruction from the control unit 23. Similarly, the memory I/F 22 reads data from the nonvolatile memory 3 in a reading process in accordance with the instruction from the control unit 23.

The control unit 23 is configured to generally control each of the components in the storage device 1. When receiving an instruction from the host 4 via the Host I/F 21, the control unit 23 controls the components in accordance with the instruction. For example, the control unit 23 gives the memory I/F 22 an instruction for writing the user data and its parity to the nonvolatile memory 3 in accordance with the instruction from the host 4. Similarly, the control unit 23 gives the memory I/F 22 an instruction for reading the user data and its parity from the nonvolatile memory 3 in accordance with the instruction from the host 4.

Furthermore, when receiving a write request from the host 4, the control unit 23 determines a storage region (memory region) in which the user data accumulated in the data buffer 25 is stored in the nonvolatile memory 3. In other words, the control unit 23 manages the place to which the user data is written. The correspondence between the logical address of the user data received from the host 4 and the physical address indicating the storage region in which the user data is stored in the nonvolatile memory 3 is stored as an address mapping table.

When receiving a read request from the host 4, the control unit 23 converts the logical address designated in the read request into the physical address with the address mapping table, and then gives the memory I/F 22 an instruction for reading the data from the physical address.

In a common NAND memory, data is written or read in a unit of data called a page, and is deleted in a unit of data called a block. A plurality of memory cells connected to a word line is referred to as a memory cell group in the present embodiment. When each of the memory cells is a single level cell (SLC), a memory cell group corresponds to a page. When each of the memory cells is a multi level cell (MLC), a memory cell group corresponds to a plurality of pages. The memory cells are connected also to a bit line while being connected to the word line. Each of the memory cells may be identified with the address for identifying the word line and the address for identifying the bit line.

The data buffer 25 temporarily stores the user data that the memory controller 2 receives from the host 4 until the data user is stored in the nonvolatile memory 3. The data buffer 25 temporarily stores the user data read from the nonvolatile memory 3 until the user data is transmitted to the host 4. The data buffer 25 includes, for example, a general-purpose memory such as a Static Random Access Memory (SRAM) or a Dynamic Random Access Memory (DRAM).

The user data transmitted from the host 4 is transferred to the internal bus 20 and stored in the data buffer 25. The Encoder/Decoder 24 encodes the data to be stored in the nonvolatile memory 3 to generate a codeword. The Encoder/Decoder 24 includes an encoder (Encoder) 26 and a decoder (Decoder) 27. The details of the encoding and decoding according to the present embodiment will be described below.

A method for protecting the data to be stored with an error correcting code in the storage device is widely known. As a specific example, a code with a plurality of constraints such as a product code or a concatenated code, which is a combination of block codes, is sometimes used as the error correcting code.

Hard-input hard-output (HIHO) decoding and soft-input soft-output (SISO) decoding are widely used as a decoding method. The SISO decoding takes more time than the HIHO decoding does although the SISO decoding can correct errors with a higher efficiency than the HIHO does. When a product code is used to protect data, the data may be decoded with either HIHO decoding or SISO decoding. For example, to decode a product code including a two dimensional codeword group, namely, a first-dimensional (horizontal) and second-dimensional (vertical) codeword group with SISO decoding, a first extrinsic value (extrinsic information) is calculated by decoding the first-dimensional code with SISO decoding, a second extrinsic value is calculated by decoding the second-dimensional code with SISO decoding using the first extrinsic value, and a first extrinsic value is calculated by decoding the first-dimensional code with SISO decoding using the second extrinsic value. Such calculations are repeated in the SISO decoding. Exchanging the extrinsic values between the decoding of different dimensional codes as described above can improve the efficiency of error correcting. Note that the extrinsic value indicates likelihood.

The correspondence between each of the common terms (a communication channel value, a priori value, a posteriori value, and an extrinsic value) used in soft decision decoding and the data stored in the storage device according to the present embodiment will be described hereinafter. When the data is read from the nonvolatile memory 3, a plurality of threshold determination processes is performed while the read level changes. The process finds the range including the threshold voltage of each of the memory cells. The range is indicated with a valuable a. A conditional probability P(a|x=0) indicates that the value of the threshold voltage is included in the range a under the condition in which a bit x written in each of the memory cells has a logical “0”. A conditional probability P(a|x=1) indicates that the value of the threshold voltage is included in the range a under the condition in which a bit x written in each of the memory cells has a logical “1”. The value obtained by taking the logarithm of the ratio of the conditional probabilities is referred to as the communication channel value (channel information) in the present embodiment. The expression indicating the communication channel value is ln(P(a|x=0)/P(a|x=1)). The ln indicates a natural logarithm in the expression.

It is assumed that a vector X that is the written data and includes a plurality of bits is included as a codeword in an error correcting code. The notation XεC indicates that the vector X is a codeword in an error correcting code C. When the probability P (x=0) in which each of the bits x has the value 0 and the probability P (x=1) in which each of the bits x has the value 1 are found from another condition rather than the code constraint C or the read range a of the threshold voltage, the value obtained by taking the logarithm of the ratio of the probabilities is referred to as the priori value (a priori information) in the present embodiment. The expression indicating the priori value is ln(P(x=0)/P(x=1)).

The soft decision decoding is commonly a method for calculating the vector X that maximizes a posterior probability P(XεC|A) or a solution approximate to the vector X under the condition that provides a vector A and the conditional probability P(A|x) of the communication channel, and also provides the vector of the priori values if the vector of the priori values is provided in advance. The provided vector A, and conditional probability P(A|x) (, and the vector of the priori value) correspond to the codeword in the code C. The vector A includes the read range of the threshold voltage as an element.

When the probability P (x=0, XεC|A) indicates that each of the bits x has the value 0 and the probability P (x=1, XεC|A) indicates that each of the bits x has the value 1, the value obtained by taking the logarithm of the ratio of the probabilities under the condition in which the vector A is received is referred to as the posteriori value (a posteriori information) in the present embodiment. The expression indicating the posteriori value is ln(P(x=0, XεC|A)/P(x=1, XεC|A)).

The value obtained by subtracting the value (the communication channel value+the priori value) from the posteriori value at each bit is referred to as the extrinsic value (extrinsic information).

When a bit belongs to a plurality of code constraints as in a product code, the extrinsic value obtained based on one of the code constraints may be used as the priori value to decode data in a soft decision decoding based on the other code constraint to which the bit belongs.

On the other hand, there are various methods to calculate an extrinsic value. For example, there is a method for calculating an extrinsic value by the following expression (1) using a decoding success rate φ. Herein, the decoding success rate φ indicates the probability that the decoding result (the decoded word) from the soft decision decoding is correct (in other words, the decoded word is identical to the transmitted codeword).

$${exLLR}_{j} = {d}_{j} ( ln ( \frac{φ + exp ( {d}_{j} ( {chLLR}_{j} + {prLLR}_{j} ) )}{1 - φ} ) ) - ( {chLLR}_{j} + {prLLR}_{j} ) \qquad ( 1 )$$

Note that, when the transmitted codeword has a code length of n, the chLLRⱼ is the jth element of the vector {chLLR₁, chLLR₂, . . . , and chLLRₙ} of the communication channel values, and the prLLRⱼ is the jth element of the vector {prLLR₁, prLLR₂, . . . , and prLLRₙ} of the priori values. The dⱼ is the jth element of the decoded word vector D={d₁, d₂, . . . , and dₙ} that is the decoded word obtained as the decoding result (a hard decision value) and expressed as a vector. However, dⱼ=+1 holds herein when a soft decision decoder estimates that xⱼ=0 holds, and dⱼ=−1 holds herein when a soft decision decoder estimates that xⱼ=1 holds. The exLLRⱼ is the jth element of the extrinsic value vector {exLLR₁, exLLR₂, . . . , and exLLRₙ}.

The decoding success rate φ can be found only when the correct solution (the transmitted codewords) is known. However, the decoder that receives a communication channel value does not have the correct solution. Thus, in the actual processes, the decoder estimates the rate φ based on the information that the decoder can obtain. As one of the actual processes, there is a method in which the rate φ is estimated on the assumption that the rate φ depends on the Dist_{des} shown in the following expression (2). In the method, the relationship between the Dist_{des} and the rate φ is found in advance. Subsequently, the rate φ is estimated based on the relationship and the Dist_{des} calculated based on the information that the decoder can obtain. Herein, the rⱼ is the jth element of the vector R={r₁, r₂, . . . , and rₙ}. The vector includes the communication channel values or the values each obtained by adding the communication value to the priori value (for example, the extrinsic value obtained by decoding in the other dimension in the product code) as the elements.

$${Dist}_{des} = {\sum }_{i ∈ DES}^{ } {( {r}_{j} - {d}_{j} )}^{2} \\ where DES = \{ j \vert ( {r}_{j} - {d}_{j} ) \cdot {d}_{j} < 0 \} \qquad ( 2 )$$

However, the extrinsic value is sometimes calculated with a low accuracy depending on the state of the communication channel or the method in which the product code is generated. In the present embodiment, the rate φ is estimated using a squared Euclidean distance between the communication channel value (received vector) and the decoded word by the following expression (3) or the information corresponding to the Euclidean distance instead of the Dist_{des}.

$${Σ ( R - D )}^{2} = {\sum }_{i = 0}^{n - 1} {r}_{i}^{2} + n - 2 {\sum }_{i = 0}^{n - 1} \vert {r}_{i} \vert + 4 {\sum }_{{r}_{i} {d}_{i} < 0}^{ } \vert {r}_{i} \vert \qquad ( 3 )$$

The terms other than the last term in the right side of the expression (3) are values determined only by the received word (communication channel value) and do not depend on the decoded word (decoding result). Thus, as shown in the following expression (4), the last term, which depends on the decoded word, in the right side of the expression (3) is defined as the distance information Dist in the present embodiment to estimate the rate φ using the distance information. In other words, in the present embodiment, the relationship among the correct decoded word (transmitted codeword), a soft input value, the distance information corresponding to the squared Euclidean distance, and the rate φ is found in advance, for example, from a simulation to estimate the rate φ based on the relationship and the distance information calculated based on the decoded word obtained by decoding the communication channel value.

$$Dist = {\sum }_{{r}_{i} {d}_{i} < 0}^{ } \vert {r}_{i} \vert \qquad ( 4 )$$

In the present embodiment, dⱼ=+1 holds when it is estimated that xⱼ=0 holds in the soft decision decoding with a code constraint, and dⱼ=−1 holds when it is estimated that xⱼ=0 holds. Then, the distance information is calculated by the expression (4). Subsequently, the rate φ is found from the relationship between the distance information and the decoding success rate φ. Then, the extrinsic value under a condition with a code constraint is calculated by the expression (1). The extrinsic value is used as the priori value for the soft decision decoding with another code constraint. The method for calculating the rate φ in the present embodiment will be described in detail below.

The encoding and decoding according to the present embodiment will be described hereinafter. A product code generated by combining two or more dimensional block codes will be described as an example herein. However, the application of the decoding method according to the present embodiment is not limited to the product code. The decoding method may be applied to any code with a plurality of restrict conditions. The decoding method according to the present embodiment may also be applied, for example, to a concatenated code.

First, the writing process in the present embodiment will be described. The control unit 23 gives the encoder 26 an instruction for encoding the data when the data is written to the nonvolatile memory 3. Meanwhile, the control unit 23 determines the place for storing the codeword in the nonvolatile memory 3 (the storage address) and indicates the address to the memory I/F 22. The encoder 26 generates a codeword by encoding the data in the data buffer 25 in accordance with the instruction from the control unit 23. The memory I/F 22 controls the storage operation of the codeword in the location that the control unit 23 indicates in the nonvolatile memory 3.

The encoder 26 generates, for example, a product code. FIG. 2 is a diagram of an exemplary configuration of the product code in the present embodiment. FIG. 2 illustrates an example in which a two-dimensional product code is used. The product code of the example illustrated in FIG. 2 includes a two-dimensional cord word group; a cord word group in a first-dimension (in a row direction, namely, a horizontal direction in FIG. 2) and second-dimension (in a column direction, namely, a direction perpendicular to the sheet of FIG. 2). A plurality of first-dimensional codewords and a plurality of second-dimensional codewords are included in the product code. However, only a first-dimensional codeword C1 and second-dimensional codeword C2 are denoted with reference signs, respectively, in FIG. 2. The Data in FIG. 2 is user data. Note that the Data indicates, for example, control data used in the controller 2 and to be protected with the product code when the data other than the user data such as the control data is protected with the same product code as for the user data. Each of the first-dimensional codewords has a code length of n_{A} bits. Each of the first-dimensional codewords has information bits of k_{A} bits. Each of the first-dimensional codewords has redundant bits, namely, Parity-A of (n_{A}−k_{A}) bits. Each of the second-dimensional codes word has a code length of n_{B} bits. Each of the second-dimensional codewords has information bits of k_{B} bits. Each of the second-dimensional codewords has redundant bits, namely, Parity-B of (n_{B}−k_{B}) bits. Cyclic Redundancy Check (CRC) bits may be added as the redundant bits for the error correcting code. Hereinafter, the whole of the codeword group illustrated in FIG. 2 is referred to as a product code.

The product code illustrated in FIG. 2 is generated with the following process. The encoder 26 encodes the data of k_{A} bits in error correcting coding (in a first encoding) and generates the Parity-A of (n_{A}−k_{A}) bits to generate the first-dimensional codeword. The n_{A} indicates the codeword length of the first-dimensional codeword. The encoder 26 encodes the data of k_{B} bits in error correcting coding (in a second encoding) and generates the Parity-B of (n_{B}−k_{B}) bits to generate the second-dimensional codeword. The n_{B} indicates the codeword length of the second-dimensional codeword. The encoder 26 encodes the data of k_{B} bits (in the second encoding) to generate the Parity-B. The data encoded in the first encoding and the second encoding is the user data received from the host 4 and the CRC bits (the CRC redundant bits) generated in accordance with the user data. The data other than the user data received from the host 4, for example, the data used for the control of the memory controller 2 may be to be encoded in the first encoding and the second encoding. For example, a block code such as a BCH code, or an RS code may be used as the error correcting code for the first encoding and the second encoding. The same error correcting code or different error correcting codes may be used for the first encoding and the second encoding. As illustrated in FIG. 2, the information bits included in the product code (the CRC bits are also included when the CRC bits are added) are included in the first-dimensional codeword and the second-dimensional codeword.

FIG. 2 illustrates an exemplary configuration of the codewords. The codewords to which the decoding method according to the present embodiment is applied is not limited to the example in FIG. 2. Each of the n_{A}, n_{B}, k_{A}, and k_{B} is used to indicate the number of bits herein. However, each of the n_{A}, n_{B}, k_{A}, and k_{B} may be used to indicate the number of symbols. The codewords to which the decoding method according to the present embodiment may be applied may be a three or more dimensional product code as described above. Alternatively, a code other than a product code may be used. In the example of FIG. 2, all of the bits of the data are protected doubly with the first-dimensional codewords and the second-dimensional codewords. However, all of the bits of the data are not necessarily protected doubly. At least a part of the data needs to be protected doubly.

The product code illustrated in FIG. 2 may be stored at any place in the nonvolatile memory 3 without a special constraint. The whole of the product code is stored, for example, in a page. Alternatively, the first-dimensional codewords may be stored in a page and the whole of the product code may be stored in a plurality of pages. Alternatively, the product code may be stored in another method.

Next, the process for reading the codeword from the nonvolatile memory 3 in the present embodiment will be described. The control unit 23 designates the address in the nonvolatile memory 3 and gives the memory I/F 22 an instruction for reading the codeword from the nonvolatile memory 3. Meanwhile, the control unit 23 instructs the decoder 27 to start decoding. The memory I/F 22 reads a received word corresponding to the codeword from the nonvolatile memory 3 in accordance with the instruction from the control unit 23. The decoder 27 decodes the received word read from the nonvolatile memory 3.

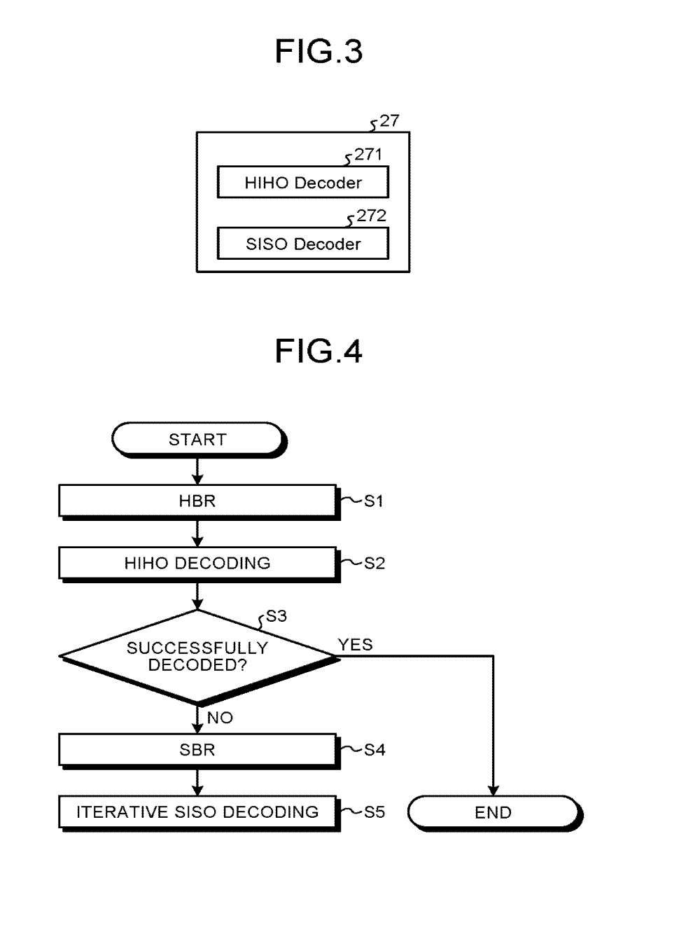

FIG. 3 is a diagram of an exemplary configuration of the decoder 27 in the present embodiment. As illustrated in FIG. 3, the decoder 27 includes an HIHO Decoder (hard decision decoder) 271 and an SISO Decoder (soft decision decoder) 272. It is assumed in the present embodiment that the codewords in each of the dimensions are generated in a method in which the codewords are encoded such that the codewords can be decoded with HIHO decoding. Thus, the codewords are decoded with HIHO decoding first. When error correcting with the HIHO decoding is failed, the codewords are decoded with SISO decoding.

FIG. 4 is a diagram of an exemplary reading process according to the present embodiment. The control unit 23 designates the address to be read and gives the memory I/F 22 an instruction for reading the data from the nonvolatile memory 3 with hard bit read (HBR). Subsequently, the memory I/F 22 performs hard bit read (step S1). The hard bit read is a method for reading each of the bits included in the codeword as a hard decision value; zero or one. The read v (hard decision value) is stored in the data buffer 25. Note that an example in which the read codeword (hard decision values) is stored in the data buffer 25 is described herein. However, a buffer configured to store a codeword (hard decision values) may be provided in the decoder 27 so as to store the codeword (hard decision values) in the buffer.

When data is written in the nonvolatile memory 3 that is a NAND memory, electrons are inserted in accordance with the data value such that the number of electrons (the amount of charge) at the floating gate corresponds to one of a plurality of distributions (threshold distributions). To simplify the description, an example of one bit/cell in which a memory cell stores a bit will be described herein. In the one bit/cell, one of the two distributions corresponds to “0” while the other corresponds to “1”. When a voltage is applied to the memory cell and the applied voltage is equal to or higher than the voltage value in accordance with the amount of charge of the memory cell, a current flows. When a voltage lower than the voltage value is applied to the memory cell, a current does not flow. Thus, the boundary voltage is determined for each memory cell in accordance with the amount of charge of the memory cell. The voltage determined in accordance with the amount of charge of the memory cell is herein referred to as a threshold voltage (Vth). Electrons are inserted in an initial state such that the number of electrons corresponds to one of the two threshold distributions. When the data is read, applying a reference read voltage that divides the two threshold distribution to the memory cell can determine whether the data stored in the memory cell is “1”.

Hard bit read is a reading method in which the nonvolatile memory 3 applies a reference read voltage to a memory cell to determine whether the data stored in the memory cell is “1” or “0”, and outputs the result from the determination. Note that the read voltage applied in the hard bit read is sometimes changed from the reference read voltage.

With reference to FIG. 4 again, the control unit 23 gives the decoder 27 an instruction for performing HIHO decoding and the decoder 27 decodes the product code stored in the data buffer 25 with HIHO decoding (step S2). Specifically, the HIHO Decoder 271 decodes the product code stored in the data buffer 25 with HIHO decoding, using the hard decision value read from the data buffer 25.

The HIHO decoding with which the codeword input as the hard decision value is decoded is, for example, bounded distance decoding. The HIHO decoding is not limited to bounded distance decoding. The HIHO Decoder 271 may use any HIHO decoding method. When the product code illustrated as an example in FIG. 2 is used, the HIHO Decoder 271 sequentially decodes the first-dimensional codewords first. When a codeword that fails to be decoded is found in the first-dimensional codewords in the product code, an error that can be corrected is corrected in the decoding of the first-dimensional codewords. Then, the second-dimensional codewords are decoded. When a codeword that fails to be decoded is found in the second-dimensional codewords, an error that can be corrected is corrected in the decoding of the second-dimensional codewords. Then, the first-dimensional codewords are decoded again. As described above, a process for repeatedly decoding the first-dimensional codewords and the second-dimensional codewords, namely, an iterative decoding process (Iterative Decoding) is performed. Note that the specific procedures in the HIHO decoding of the product code are not limited to the procedures described above. Any procedures may be performed in the HIHO decoding. For example, the decoding is not necessarily repeated in the HIHO decoding.

The HIHO Decoder 271 determines after step S2 whether all of the codewords included in the product code are successfully decoded, and notifies the result from the determination to the control unit 23. The control unit 23 determines based on the notification from the HIHO Decoder 271 whether all of the codewords included in the product code are successfully decoded (step S3). When all of the codewords are successfully decoded (Yes in step S3), the reading process is terminated. Note that the control unit 23 determines in step S3 whether all of the codewords in at least one of the dimensions included in the product code are successfully decoded. When redundant bits such as CRC bits are added as an error correcting code, the codewords may also be checked with the error correcting code in the determination in step S3 whether the codewords are successfully decoded.

When the control unit 23 determines that a codeword included in the product code fails to be decoded (No in step S3), the control unit 23 designates the address to be read and gives the memory I/F 22 an instruction for reading the data of the address with soft bit read (SBR) from the nonvolatile memory 3. Then, the memory I/F 22 reads the data with soft bit read in which the data is read as a soft decision value (step S4).

In the present embodiment, the codeword read with soft bit read from the nonvolatile memory 3 is the input for the SISO decoding in the SISO Decoder 272. By the soft bit read, the value obtained by taking the logarithm of the ratio of the probability (or likelihood) that the value stored in the memory cell in the nonvolatile memory 3 is “0” to the probability (or likelihood) that the value is “1”, namely, the Log Likelihood Ratio (LLR) is obtained.

Alternatively, when it is assumed that the logarithm of the ratio of the probability that the value stored in the nonvolatile memory 3 is “0” to the probability that the value is “1” is known, the known logarithm is referred to as a priori value. The SISO Decoder 272 decodes each of the codewords in each of the dimensions, using the communication channel value, namely, the LLR and the priori value as the input. In other words, the SISO Decoder 272 finds the most likely codeword among the codewords satisfying the code constraint as the decoded words, using the communication channel value, namely, the LLR and the priori value as the input. The SISO Decoder 272 decodes each of the codewords in each of the dimensions. The decoding provides the value obtained by taking the logarithm of the ratio of the probability that each of the bits of a codeword is “0” to the probability that each of the bits is “1”, namely, log a posteriori probability ratio. The log a posteriori probability ratio is referred to a posteriori value in the present embodiment.

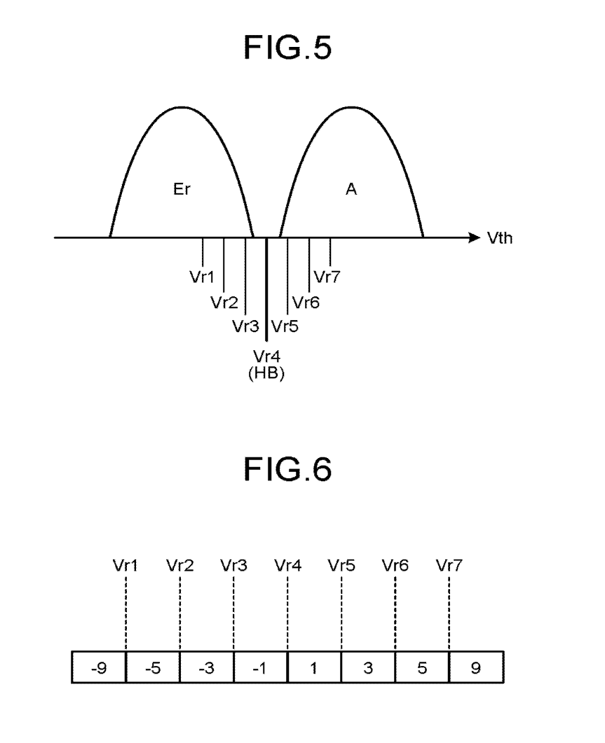

FIG. 5 is an explanatory diagram of soft bit read. The threshold voltage is shown on the horizontal axis and the frequency is shown on the vertical axis in FIG. 5. FIG. 5 illustrates an exemplary single level cell that stores one bit/cell. The Erase (Er) distribution on the left side corresponds to the data value of “1” and the A distribution on the right side corresponds to the data value of “0”. In addition to the reference read voltage used in hard bit read, a plurality of read voltages on both sides of the reference read voltage is used for the reading in soft bit read. FIG. 5 illustrates exemplary soft bit read with seven read voltages in total. The read voltage indicated as Vr4 (HB) is the reference read voltage used in the hard bit read. The seven read voltages; the voltage Vr4, voltages Vr1, Vr2, and Vr3 that are lower than the voltage Vr4, and voltages Vr5, Vr6, and Vr7 that are higher than the voltage Vr4 are used for the reading in the soft bit read. Note that the number of read voltages in the soft bit read is not limited to seven.

The LLR can be found from the result from the determination whether the threshold voltage of each of the memory cells is equal to or higher than each of the read voltages, for example, with an LLR table. FIG. 6 is a diagram of an exemplary LLR table. For example, when it is determined that the threshold voltage of a memory cell is lower than the voltage Vr1, the LLR is −9. When it is determined that the threshold voltage of a memory cell is equal to or higher than the voltage Vr1 and lower than the voltage Vr2, the LLR is −5. FIG. 6 illustrates an example and the LLR table is not limited to the example in FIG. 6. Alternatively, the LLR may be found, for example, with a calculation expression without an LLR table. In the present embodiment, the process for converting the data into an LLR with the soft bit read means that the data is read as a soft decision value from the nonvolatile memory 3.

Either the memory controller 2 or the nonvolatile memory 3 may convert data into an LLR from the result from the determination whether the threshold voltage of each of the memory cells is equal to or higher than each of the read voltages. When the memory controller 2 converts data into an LLR, the nonvolatile memory 3 outputs, for example, the information indicating the region in which the threshold voltage of each of the memory cells is included among eight regions; a region including voltages lower than the voltage Vr1, a region including voltages equal to or higher than the voltage Vr1 and lower than the voltage Vr2, a region including voltages equal to or higher than the voltage Vr2 and lower than the voltage Vr3, a region including voltages equal to or higher than the voltage Vr3 and lower than the voltage Vr4, a region including voltages equal to or higher than the voltage Vr4 and lower than the voltage Vr5, a region including voltages equal to or higher than the voltage Vr5 and lower than the voltage Vr6, a region including voltages equal to or higher than the voltage Vr6 and lower than the voltage Vr7, and a region including voltages equal to or higher than the voltage Vr7. Then, the memory I/F 22 finds the LLR in accordance with the LLR table and the information output from the nonvolatile memory 3, and outputs the found LLR to the decoder 27.

A single level cell that stores one bit/cell is described as an example with reference to FIGS. 5 and 6. Note that, however, the data is read with a plurality of read voltages at each of the boundaries in the threshold distribution in a multi level cell, similarly to the exemplary single level cell. Then, the LLR is calculated in accordance with the results from the reading at the read voltages.

With reference to FIG. 4 again, the control unit 23 gives the decoder 27 an instruction for performing iterative SISO decoding in which the codes in the first dimension and the codes in the second dimension are repeatedly decoded with SISO decoding. The decoder 27 decodes the codes with iterative SISO decoding (step S5). Specifically, the SISO decoder 272 decodes the product code input as the LLR with SISO decoding. The iterative SISO decoding will be described in detail below.

The process described above enables a high-speed reading when the errors may be corrected with the hard bit read and HIHO decoding and the decoding is completed only with the hard bit read and HIHO decoding. On the other hand, when the errors fail to be corrected with the hard bit read and HIHO decoding, performing SISO decoding with a high efficiency of correcting errors can improve the efficiency of correcting errors. The hard bit read and HIHO decoding is performed first in the present embodiment and, when the errors fail to be corrected with the hard bit read and HIHO decoding, the soft bit read and SISO decoding is subsequently performed. Note that, however, the soft bit read and SISO decoding may be performed first without the hard bit read and HIHO decoding.

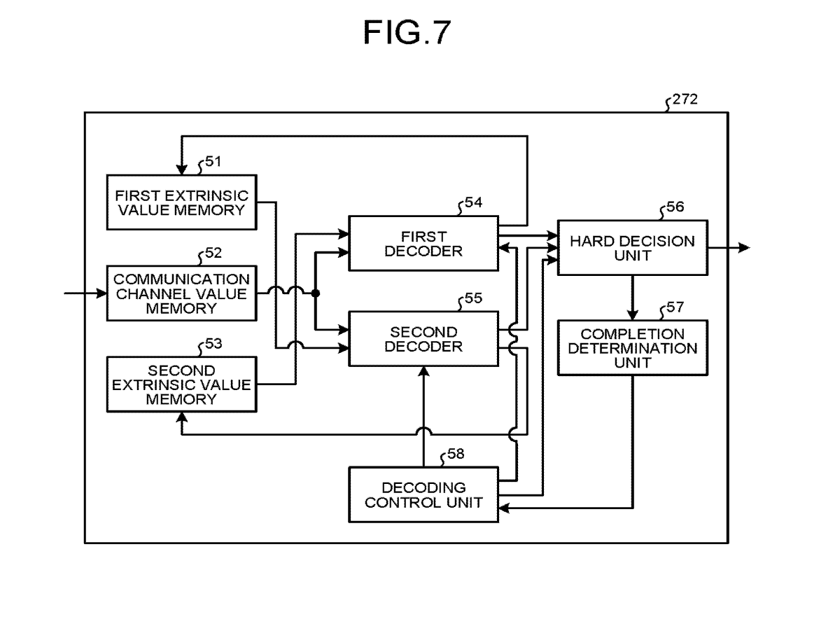

Next, the SISO decoding according to the present embodiment will be described. FIG. 7 is a diagram of an exemplary configuration of the SISO Decoder 272. As illustrated in FIG. 7, the SISO Decoder 272 includes a first extrinsic value memory 51, a communication channel value memory 52, a second extrinsic value memory 53, a first decoder 54, a second decoder 55, a hard decision unit 56, a completion determination unit 57, and a decoding control unit 58.

The first decoder 54 decodes the first-dimensional codewords with SISO decoding. The second decoder 55 decodes the second-dimensional codewords with SISO decoding. Hereinafter, the SISO decoding is referred to also merely as soft decision decoding. The first decoder 54 and the second decoder 55 may perform the soft decision decoding in any specific method without a special constraint.

The SISO Decoder 272 according to the present embodiment decodes data, using an extrinsic value obtained in another dimension as the priori value. For example, the first decoder 54 uses the extrinsic value (the second extrinsic value) obtained by decoding the second-dimensional codeword stored in the second extrinsic value memory 53 to decode a first-dimensional codeword. Similarly, the second decoder 55 uses the extrinsic value (the first extrinsic value) obtained by decoding the first-dimensional codeword stored in the first extrinsic value memory 51 to decode the second-dimensional codeword.

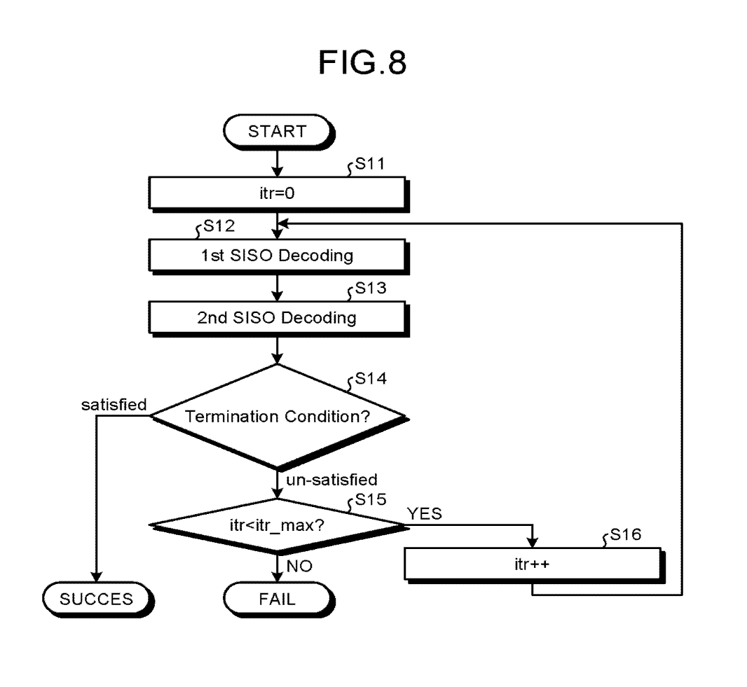

FIG. 8 is a flowchart of an exemplary iterative SISO decoding process according to the present embodiment. First, the decoding control unit 58 initializes a counter itr that indicates the number of iteration of SISO decoding and sets the counter at zero when receiving an instruction for starting SISO decoding from the control unit 23 (step S11). Next, the SISO Decoder 272 decodes a first-dimensional codeword group included in a product code with a first SISO decoding process (step S12). The first SISO decoding process will specifically be described below. The decoding control unit 58 gives the first decoder 54 an instruction for decoding the codewords. When receiving the instruction from the decoding control unit 58, the first decoder 54 reads the LLR corresponding to each bit of each of the first-dimensional codewords included in the product code from the communication channel value memory 52. Furthermore, the first decoder 54 reads the extrinsic value that corresponds to each bit of the first-dimensional codewords and that is obtained as the result from the second-dimensional SISO decoding from the second extrinsic value memory 53. Then, the first decoder 54 determines the extrinsic value as the priori value in the first dimension, and uses the extrinsic value as the input for the first SISO decoding. However, the priori value is set at a predetermined value (for example, 0) in the first SISO decoding when the first SISO decoding is the first decoding process of the iterative decoding process. Then, the first decoder 54 decodes each of the first-dimensional codewords with SISO decoding, using the LLR and the priori value. Then, the first decoder 54 stores the extrinsic values obtained from the SISO decoding in the first extrinsic value memory 51.

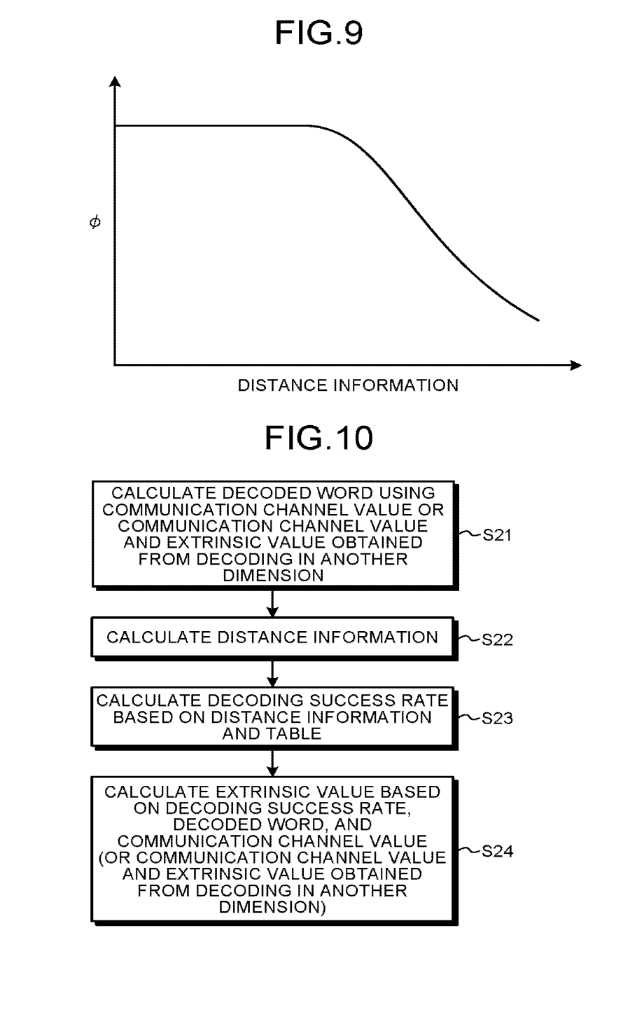

The method for calculating an extrinsic value in the first decoder 54 and the second decoder 55 according to the present embodiment will be described. As described above, the decoding success rate φ is calculated based on the distance information in the present embodiment, and the extrinsic value is calculated by the expression (1) using the decoding success rate φ. FIG. 9 is a conceptual diagram of an exemplary relationship between the distance information and the decoding success rate φ in the present embodiment. The relationship between the distance information and the decoding success rate φ is previously found, for example, from a simulation in the present embodiment. Note that the relationship between the distance information and the decoding success rate φ in the first-dimensional codeword may differ from the relationship in the second-dimensional codeword because the relationship between the distance information and the decoding success rate φ depends, for example, on the encoding method. Thus, two tables indicating the relationship between the distance information and the decoding success rate φ are prepared. One is for decoding the first-dimensional codewords (a first table) and the other is for decoding the second-dimensional codewords (a second table). Each of the first decoder 54 and the second decoder 55 holds an appropriate table. In other words, the first decoder 54 holds the first table, and the second decoder 55 holds the second table. When the first-dimensional codewords and the second-dimensional codewords are encoded with the same encoding method, the first decoder 54 and the second decoder 55 may use the same table. Note that FIG. 9 illustrates the concept and the actual relationship between the distance information and the decoding success rate φ is not limited to the relationship illustrated in FIG. 9.

FIG. 10 is a flowchart of an exemplary process for calculating an extrinsic value in the present embodiment. The operation of the first decoder 54 will be described as an example. Note that, however, the operation of the second decoder 55 is the same as that of the first decoder 54 except that the second decoder 55 decodes the second-dimensional codewords.

The first decoder 54 calculates an decoded word with soft decision decoding, using a communication channel value (or a communication channel value+a priori value (the priori value is the extrinsic value obtained by the decoding in another dimension)) (step S21). Next, the first decoder 54 calculates the distance information by the expression (4) based on the decoded word and the communication channel value (or the communication channel value+the priori value) (step S22). Subsequently, as described in the expression (4), the first decoder 54 calculates the position of the bit of which error is corrected in the decoded word, in other words, calculates the sum of the absolute values of rᵢ of the i satisfying dᵢrᵢ<0 so as to use the calculated value as the distance information. The i satisfying dᵢrᵢ<0 may be found by actually calculating dᵢrᵢ for every i. Alternatively, the i satisfying dᵢrᵢ<0 may be found with an error vector (the information indicating the position of the error bit) obtained with soft decision decoding.

Next, the first decoder 54 calculates the decoding success rate φ, using the distance information and the table (step S23). Subsequently, the first decoder 54 calculates the extrinsic value by the expression (1) based on the decoding success rate φ, the decoding result, and the communication channel value (or the communication channel value+the priori value) (step S24).

With reference to FIG. 8 again, the SISO Decoder 272 decodes the second-dimensional codeword group included in the product code in a second SISO decoding after step S12 (step S13). More specifically, the second SISO decoding process will be described below. The decoding control unit 58 gives the second decoder 55 an instruction for decoding the codewords. When receiving the instruction from the decoding control unit 58, the second decoder 55 reads the LLR corresponding to each bit of each of the second-dimensional codewords included in the product code from the communication channel value memory 52. Furthermore, the second decoder 55 reads the extrinsic value that corresponds to each bit of each of the second-dimensional codewords and that is obtained as the result from the first-dimensional SISO decoding from the first extrinsic value memory 51. Subsequently, the second decoder 55 determines the extrinsic value as the priori value in the second dimension, and uses the extrinsic value as the input for the first SISO decoding. Then, the second decoder 55 decodes each of the codewords with SISO decoding, using the LLR and the priori value. The second decoder 55 stores the extrinsic value obtained from the SISO decoding in the second extrinsic value memory 53. The second extrinsic value is calculated with the process described with reference to FIG. 10. The second decoder 55 outputs the posteriori value of each of the bits of each of the codewords obtained in the second SISO decoding to the hard decision unit 56.

The SISO Decoder 272 determines based on the result from the hard decision of the posteriori value whether to terminate the SISO decoding (step S14). Specifically, the hard decision unit 56 determines the posteriori value of each of the bits of each of the codewords with hard decision, and outputs the posteriori value to the completion determination unit 57. The completion determination unit 57 determines based on the result from the hard decision whether to terminate the SISO decoding, and outputs the determination result to the decoding control unit 58. For example, one of the following conditions or the combination of two or more of the conditions may be used as the check for determining the termination. The first condition is that the parity check in the first-dimensional codewords is satisfied (no error is found). The second condition is that the parity check in the second-dimensional codewords is satisfied (no error is found). The third condition is that the check on the error detecting code is satisfied (no error is found) when the redundant bits such as CRC bits are added as an error detecting code.

When determining to terminate the SISO decoding (satisfied in step S14), the SISO Decoder 272 determines the success of the SISO decoding and terminates the SISO decoding. When it is determined that the condition for terminating the SISO decoding is not satisfied (un-satisfied in step S14), the decoding control unit 58 determines whether the counter itr that indicates the number of iteration of the SISO decoding indicates the number smaller than the maximum number itr max of iteration of the SISO decoding (step S15). When the counter itr indicates the number smaller than the number itr max (Yes in step S15), the decoding control unit 58 increases the number of the counter itr by one (step S16), and the process goes back to step S12. When the number of the counter itr is equal to or larger than the number itr max (No in step S15), it is determined that the decoding is failed and the SISO decoding is terminated.

As described above, an extrinsic value is calculated by the decoding of the codewords in each of the dimensions, and the extrinsic value is calculated with the decoding success rate calculated based on the distance information in the present embodiment. Thus, a product code is decoded with an iteration process in the present embodiment while the extrinsic value obtained by the decoding of the codewords in another dimension is used as the priori value for the decoding of the codewords in each of the dimensions in the SISO decoding. This can increase the efficiency of correcting errors with a simple process.

Note that the distance between the decoded word and the soft decision input shown in the expression (3) may be used as the distance information although the distance information shown in the expression (4) is used as an example in the present embodiment.

Note that the present invention may be applied in order to repeatedly decode not only a product code but also a code with a plurality of constraints in SISO decoding although an example in which the product code including the first-dimensional codewords (the first codewords) and the second-dimensional codewords (the second codewords) is decoded with the SISO decoding is described in the present embodiment. For example, the present invention may be applied for decoding of a concatenated code including the first codewords and the second codewords.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory controller comprising a soft decision decoder, the soft decision decoder including:
a first decoder configured to perform a first decoding using a first received word as a first set of soft input values, the first received word corresponding to a first codeword read as a set of soft decision values from a nonvolatile memory, calculate first distance information indicating a squared Euclidean distance between a first decoded word obtained by the first decoding and the first set of soft input values based on the first decoded word, calculate a first decoding success rate based on the first distance information, the first decoding success rate indicating a probability that the first decoded word is a correct decoding result, calculate a first set of extrinsic values based on the first decoding success rate, and output the first set of extrinsic values; and
a second decoder configured to perform a second decoding using a first result as a set of second soft input values, the first result being obtained by adding a second received word to a rearranged first set of extrinsic values, the second received word corresponding to a second codeword read as a set of soft decision values from the nonvolatile memory, the rearranged first set of extrinsic values corresponding to the second codeword, calculate second distance information indicating a squared Euclidean distance between a second decoded word obtained by the second decoding and the second set of soft input values based on the second decoded word, calculate a second decoding success rate based on the second distance information, the second decoding success rate indicating a probability that the second decoded word is a correct decoding result, calculate a second set of extrinsic values based on the second decoding success rate, and output the second set of extrinsic values.

2. The memory controller according to claim 1, wherein the soft decision decoder further includes a completion determination unit configured to determine based on a decoding result from the second decoding whether to terminate the decoding,
the soft decision decoder repeats the first decoding and the second decoding until the completion determination unit determines to terminate the decoding, and
the first decoder uses a second result as the first set of soft input values when the second set of extrinsic values are calculated, the second result being obtained by adding the first received word to the rearranged second set of the second extrinsic values corresponding to the first codeword.

3. The memory controller according to claim 1, wherein the first distance information includes a sum of values proportional to absolute values of the first soft input values corresponding to all of bits corrected in the first decoded word.

4. The memory controller according to claim 1, wherein the first decoder has a first table indicating a correspondence between the first distance information and the first decoding success rate to calculate the first decoding success rate based on the first table and the first distance information obtained by the first decoding, and
the second decoder has a second table indicating a correspondence between the second distance information and the second decoding success rate to calculate the second decoding success rate based on the second table and the second distance information obtained by the second decoding.

5. The memory controller according to claim 1, wherein the first codeword is a first-dimensional codeword included in a product code, and the second codeword is a second-dimensional codeword included in the product code.

6. The memory controller according to claim 1, further comprising:
a hard decision decoder configured to decode the first received word corresponding to the first codeword read as a set of hard decision values from the nonvolatile memory with hard decision decoding, and decode the second received word corresponding to the second codeword read as a hard decision value from the nonvolatile memory with hard decision decoding, wherein
the memory controller reads the first received word and the second received word as sets of soft decision values from the nonvolatile memory and the soft decision decoder performs the first decoding and the second decoding based on the read soft decision values when the hard decision decoding is not successful.

7. A storage device comprising:
a nonvolatile memory; and
a soft decision decoder, the soft decision decoder including:
a first decoder configured to perform a first decoding using a first received word as a first set of soft input values, the first received word corresponding to a first codeword read as a set of soft decision values from the nonvolatile memory, calculate first distance information indicating a squared Euclidean distance between a first decoded word obtained by the first decoding and the first set of soft input values based on the first decoded word, calculate a first decoding success rate based on the first distance information, the first decoding success rate indicating a probability that the first decoded word is a correct decoding result, calculate a first set of extrinsic values based on the first decoding success rate, and output the first set of extrinsic values; and
a second decoder configured to perform a second decoding using a first result as a second set of soft input values, the first result being obtained by adding a second received to a rearranged first set of extrinsic values, the second received word corresponding to a second codeword read as a set of soft decision values from the nonvolatile memory, the rearranged first set of extrinsic values corresponding to the second codeword, calculate second distance information indicating a squared Euclidean distance between a second decoded word obtained by the second decoding and the second set of soft input values based on the second decoded word, calculate a second decoding success rate based on the second distance information, the second decoding success rate indicating a probability that the second decoded word is a correct decoding result, calculate a second set of extrinsic values based on the second decoding success rate, and output the second set of extrinsic values.

8. The storage device according to claim 7, wherein the soft decision decoder further includes a completion determination unit configured to determine based on a decoding result from the second decoding whether to terminate the decoding,
the soft decision decoder repeats the first decoding and the second decoding until the completion determination unit determines to terminate the decoding, and
the first decoder uses the a second result as the first soft input value when the second set of extrinsic values are calculated, the second result being obtained by adding the first received word to the rearranged second set of extrinsic values corresponding to the first codeword.

9. The storage device according to claim 7, wherein the first distance information includes a sum of values proportional to absolute values of the first soft input values of all of bits corrected in the first decoded word.

10. The storage device according to claim 7, wherein the first decoder has a first table indicating a correspondence between the first distance information and the first decoding success rate to calculate the first decoding success rate based on the first table and the first distance information obtained by the first decoding, and
the second decoder has a second table indicating a correspondence between the second distance information and the second decoding success rate to calculate the second decoding success rate based on the second table and the second distance information obtained by the second decoding.

11. The storage device according to claim 7, wherein the first codeword is a first-dimensional codeword included in a product code, and the second codeword is a second-dimensional codeword included in the product code.

12. The storage device according to claim 7, wherein the decoder further includes:
a hard decision decoder configured to decode the first received word corresponding to the first codeword read as a hard decision value from the nonvolatile memory with hard decision decoding, and decode the second received word corresponding to the second codeword read as a hard decision value from the nonvolatile memory with hard decision decoding, and
the memory controller reads the first received word and the second received word as soft decision values from the nonvolatile memory and the soft decision decoder performs the first decoding and the second decoding based on the read soft decision values when the word is not successfully decoded with the hard decision decoding.

13. A decoding method comprising:
performing a first decoding using a first received word as a first set of soft input values, the first received word corresponding to a first codeword read as a set of soft decision values from a nonvolatile memory;
calculating first distance information indicating a squared Euclidean distance between a first decoded word obtained by the first decoding and the first soft input value based on the first decoded word;
calculating a first decoding success rate based on the first distance information, the first decoding success rate indicating a probability that the first decoded word is a correct decoding result;
calculating a first set of extrinsic values based on the first decoding success rate;
outputting the first set of extrinsic values;
performing a second decoding using a first result as a second set of soft input values, the first result being obtained by adding a second received word to a rearranged first set of extrinsic values, the second received word corresponding to a second codeword read as a set of soft decision values from the nonvolatile memory, the rearranged first set of extrinsic values corresponding to the second codeword;
calculating second distance information indicating a squared Euclidean distance between a second decoded word obtained by the second decoding and the second set of soft input values based on the second decoded word;
calculating a second decoding success rate based on the second distance information, the second decoding success rate indicating a probability that the second decoded word is a correct decoding result;
calculating a set of second extrinsic values based on the second decoding success rate; and
outputting the set of second extrinsic values.

14. The decoding method according to claim 13, further comprising:
performing a completion determination process for determining based on a decoding result from the second decoding whether to terminate the decoding; and
repeating the first decoding and the second decoding until it is determined to terminate the decoding with the completion determination process, wherein
a first decoding includes using a second result as the first set of soft input values when the second set of extrinsic values are calculated, the second result being obtained by adding the first received word to the second set of extrinsic values corresponding to the first codeword.

15. The decoding method according to claim 13, wherein the first distance information is a sum of values proportional to absolute values of the first soft input values of all of bits corrected in the first decoded word.

16. The decoding method according to claim 13, further comprising:
having a first table indicating a correspondence between the first distance information and the first decoding success rate to calculate the first decoding success rate based on the first table and the first distance information obtained by the first decoding, and
having a second table indicating a correspondence between the second distance information and the second decoding success rate to calculate the second decoding success rate based on the second table and the second distance information obtained by the second decoding.

17. The decoding method according to claim 13, wherein the first codeword is a first-dimensional codeword included in a product code, and the second codeword is a second-dimensional codeword included in the product code.

18. The decoding method according to claim 13, further comprising:
performing hard decision decoding, the hard decision decoding including decoding the first received word corresponding to the first codeword read as a set of hard decision values from the nonvolatile memory with hard decision decoding and the second received word corresponding to the second codeword read as a set of hard decision values from the nonvolatile memory, wherein
the first received word and the second received word are read as soft decision values from the nonvolatile memory and the first decoding and the second decoding based on the read soft decision values are perfumed when the hard decision decoding is not successful.
